(19) United States
(12) Patent Application Publication
(10) Pub. No.: US 2017/0213927 A1
(43) Pub. Date: Jul. 27, 2017

(54) ELECTRICAL AND/OR ELECTRONIC DEVICE COMPRISING A SYSTEM FOR MECHANICALLY PROTECTING AT LEAST ONE ELECTRICAL AND/OR ELECTRONIC COMPONENT

(71) Applicant: COMMISSARIAT A L'ENERGIE ATOMIQUE ET AUX ENERGIES ALTERNATIVES, Paris (FR)

(72) Inventor: Eric PILAT, Brison-Saint-Innocent (FR)

(73) Assignee: COMMISSARIAT A L'ENERGIE ATOMIQUE ET AUX ENERGIES ALTERNATIVES, Paris (FR)

(21) Appl. No.: 15/328,095

(22) PCT Filed: Jul. 27, 2015
(86) PCT No.: PCT/EP2015/067100

§ 371 Date: Jan. 23, 2017

(30) Foreign Application Priority Data
Jul. 28, 2014 (FR) 1457272

(51) Int. Cl. H01L 31/048; H01L 31/05

(52) U.S. Cl. CPC H01L 31/0488; H01L 31/0504; H01L 31/0481

(57) ABSTRACT

An electrical and/or electronic device including at least two electrical and/or electronic components, each including two opposite faces, at least one electrical contact element arranged against at least one of the two opposite faces of each of the at least two electrical and/or electronic components, and each of them is mechanically protected by a mechanical protection system including at least one protective element, superimposed on one or plural electrical and/or electronic components that it protects such that at least one of the two opposite faces of the electrical and/or electronic components is arranged facing the at least one protective element, and at least one deformation absorption element is arranged in at least one space formed between the at least one protective element and at least one electrical and/or electronic component that it protects.

### TECHNICAL FIELD

The present invention relates to the field of electrical and/or electronic devices comprising electrical and/or electronic components, for example encapsulated. The invention particularly applies to devices comprising at least one transparent face enabling the electrical and/or electronic components to emit and/or to receive a luminous flux.

The invention particularly relates to the field of photovoltaic modules that comprise a set of photovoltaic cells connected together electrically, and notably so-called “crystalline” photovoltaic cells, that is to say which are based on silicon crystals or silicon polycrystals.

The invention also relates, in a more general manner, to the field of electrical and/or electronic devices which comprise mechanically fragile components, and in particular optoelectronic components, for example encapsulated, such as CDD (charge coupled devices), CMOS type sensors, or instead the field of flat screens, for example of LCD (liquid crystal display), plasma or LED (light emitting diode) type.

The invention thus proposes an electrical and/or electronic device comprising a system for mechanically protecting at least one electrical and/or electronic component, as well as a method for producing such an electrical and/or electronic device.

### PRIOR ART

A photovoltaic module is an assembly of photovoltaic cells arranged side by side between a first transparent layer, for example based on glass, forming a front face of the photovoltaic module and a second layer, it also being able to be transparent, and for example based on glass, metal or plastic, forming a rear face of the photovoltaic module.

The photovoltaic cells are electrically connected together in series by front and rear electrical contact elements, known as connecting conductors, and formed for example by copper strips, respectively arranged against the front faces (faces located facing the front face of the photovoltaic module intended to receive the luminous fluxes) and rear faces (faces located facing the rear face of the photovoltaic module) of each of the photovoltaic cells.

Furthermore, in order that the photovoltaic module forms a rigid assembly, said module may comprise a frame surrounding an assembly of laminated layers forming an encapsulating assembly in which the photovoltaic cells are arranged. In a variant, the photovoltaic module could also be without such a frame, which may for example be the case for photovoltaic modules arranged vertically, modules with double glazing or instead modules with thicknesses greater than 5 mm.

During the production of the photovoltaic module, two layers (or films) of ethylene vinyl acetate (EVA) are generally used, between which are arranged the photovoltaic cells and the connecting conductors of the cells, as well as a glass layer superimposed on the EVA layer located facing the front faces of the photovoltaic cells, and a base layer of glass or a composite material such as a laminate based on polyvinyl fluoride (PVF) or polyethylene terephthalate (PET), arranged against the other EVA layer located facing the rear faces of the photovoltaic cells. Nevertheless, after this operation of lamination of the layers, the two layers of EVA have melted to form only a single layer in which the photovoltaic cells are immersed.

This known principle of encapsulation of photovoltaic cells to form a rigid photovoltaic module is not entirely satisfactory and has several drawbacks.

Firstly, such a design is expensive, the techniques implemented to carry out this encapsulation representing around 30% of the total cost of the photovoltaic module.

Also, in order to reduce the production cost of photovoltaic modules and notably to economise the use of silicon in the crystalline photovoltaic cells, a first trend aims to design thinner and thinner photovoltaic cells, to the detriment of their mechanical robustness. In fact, the preceding design does not enable good mechanical protection of the photovoltaic cells to be ensured.

In addition, a second trend aims to use such photovoltaic cells, and notably crystalline photovoltaic cells, in more and more restrictive applications which place them under considerable duress with regard to their mechanical strength.

Yet, photovoltaic cells, and notably crystalline photovoltaic cells, are supple but very fragile and capable of breaking easily.

In particular, these photovoltaic cells can fissure when they are subjected to severe stresses, for example transport linked vibrations. The fissures formed on the photovoltaic cells are sometimes not even visible and do not cause obvious immediate electrical effects, which complicates their detection. In certain situations, such as for example for the so-called NICE encapsulation technology (New Industrial solar Cell Encapsulation technology, developed by Appolon Solar and as described in the patent application WO 03/038911 A1), such stresses, applied to the photovoltaic cells, can also result from temperature variations, for example comprised between around −40° C. and +90° C., which cause pressure variations in the internal volume in which the cells are encapsulated. The greater the surface irregularities (those of glass substrates in particular) inside the volume, the higher the localised stresses.

Yet, such fissures in a photovoltaic cell may, from the moment of their formation or later during the lifetime of the cell, separate and isolate a part of the cell vis-à-vis the electrical contacts of the cell, being able to lead to a loss of a part of the electricity produced by the cell. Among the most critical breaking configurations of photovoltaic cells, “dendritic”, “varied” or instead “exterior parallel” type breaking configurations may notably be cited.

For this reason there exists a need to succeed in efficiently protecting the photovoltaic cells from all risks of damage that they may undergo, and notably those linked to impacts and strong mechanical loads occurring during their lifetime and/or during their handling or transport, to which the photovoltaic modules designed according to the principle of the prior art described above do not succeed in meeting in a significant manner.

Furthermore, the aforementioned drawbacks for photovoltaic modules may also be found in other types of electrical and/or electronic devices comprising mechanically fragile components, and notably in optoelectronic devices such as imaging devices (CCD, CMOS, etc.) or electronic display type devices (LCD, plasma, LED, etc.) comprising encapsulated components, and in which it is sought to obtain good electrical contact with the component(s) of the device despite the surface irregularities of the layers between which the component(s) are encapsulated.

### DESCRIPTION OF THE INVENTION

The aim of the invention is thus to overcome at least partially the aforementioned needs and drawbacks of the prior art.

It notably aims to propose an alternative solution for imparting more robustness to an electrical and/or electronic device comprising electrical and/or electronic components, and notably a photovoltaic module comprising photovoltaic cells, in particular crystalline photovoltaic cells.

The invention thus relates, according to one of its aspects, to an electrical and/or electronic device comprising:
at least two electrical and/or electronic components, each of said at least two electrical and/or electronic components comprising two opposite faces,
at least one electrical contact element arranged against at least one of the two opposite faces of each of said at least two electrical and/or electronic components, characterised in that each of said at least two electrical and/or electronic components is mechanically protected by a mechanical protection system comprising at least one protective element, which is superimposed on one or several electrical and/or electronic components that it protects such that at least one of the two opposite faces of the electrical and/or electronic component(s) is arranged facing said at least one protective element, and in that at least one deformation absorption element is arranged in at least one space formed between said at least one protective element and at least one electrical and/or electronic component that it protects.

Thanks to the invention, it may thus be possible to provide an alternative solution for mechanically protecting the electrical and/or electronic components of an electrical and/or electronic device, and notably the photovoltaic cells of a photovoltaic module. Moreover, the invention may make it possible to impart robustness to an electrical and/or electronic device, notably to the electrical and/or electronic components that it comprises, while remaining satisfactory in terms of weight and flexibility of the electrical and/or electronic device. The system for mechanically protecting the electrical and/or electronic device according to the invention may play the role of shield which prevents any contact between the exterior environment and the electrical and/or electronic component(s) that it protects.

The electrical and/or electronic device according to the invention may moreover comprise one or more of the following characteristics taken in isolation or according to any technically possible combinations thereof.

Said at least one deformation absorption element may be included in a deformation absorption system.

The mechanical protection system and the deformation absorption system may make it possible to protect the electrical and/or electronic component(s) that they protect from impacts and mechanical loads to which they can be subjected during the lifetime of the device according to the invention and/or during handling or transport operations.

The mechanical protection system may thus be similar to a shield superimposed on one or several electrical and/or electronic components for their protection.

The protective element(s) may notably have the shape of a shell superimposed on one or several electrical and/or electronic components.

Advantageously, the presence of a deformation absorption element may make it possible to avoid contact between the external face of the device (front or rear) and an electrical and/or electronic component associated with the deformation absorption element. In this way, it is possible to avoid the risks of damaging, and notably of fissuring, the electrical and/or electronic components of the device.

The device according to the invention may comprise a plurality of electrical contact elements such that each of the two opposite faces of each of said at least two electrical and/or electronic components comprises at least one of the electrical contact elements arranged against said each of the two opposite faces of said each of said at least two electrical and/or electronic components.

The layer of material forming the front face of the device according to the invention, being able to notably comprise one or more protective elements, may be transparent, the electrical and/or electronic components being able to be capable of emitting and/or receiving at least one luminous flux through the front face of the device, for example through one or more protective elements. The protective element(s) may thus be transparent.

The term “transparent” signifies that the material of the layer forming the front face of the device, notably the material of a protective element, is at least partially transparent to visible light, allowing at least around 80% of this light to get through.

Preferentially, each electrical and/or electronic component may be protected mechanically by at least one protective element that is specific thereto.

In other words, the device according to the invention may comprise, for each electrical and/or electronic component, at least one protective element superimposed on the electrical and/or electronic component that it protects, while being arranged facing at least one of the two opposite faces of said electrical and/or electronic component. Thus, a given protective element may only protect a single electrical and/or electronic component.

In a variant, it may be envisaged that a same protective element covers at least two separate electrical and/or electronic components. In other words, the device according to the invention may comprise a protective element superimposed on at least two separate electrical and/or electronic components. Thus, such a protective element may be arranged facing at least one of the two opposite faces of at least one first electrical and/or electronic component and facing at least one of the two opposite faces of at least one second electrical and/or electronic component. Said at least one of the two opposite faces of each of said at least one first and second electrical and/or electronic components may in particular be situated on a same side of the device, that is to say all on the front side or all on the rear side of the device.

Each electrical and/or electronic component may be taken between two protective elements, a first protective element being arranged in superposition with respect to the electrical and/or electronic component(s) that it protects, facing one of its two opposite faces, and a second protective element being arranged in superposition with respect to the electrical and/or electronic component(s) that it protects, facing the other of its two opposite faces.

The first protective element and the second protective element may be assembled together, notably by bonding.

The first protective element and the second protective element may respectively form, at least in part, front and rear faces of the electrical and/or electronic device, between which are only arranged the electrical and/or electronic component, that the first and second protective elements protect, said at least one electrical contact element that is associated with it and at least one first deformation absorption element and a second absorption element arranged on either side of said electrical and/or electronic component.

The device according to the invention may moreover comprise an encapsulating assembly advantageously formed from at least one encapsulation material, and preferably from at least two layers of encapsulation material. Said at least two electrical and/or electronic components are thus encapsulated, notably between the two layers of encapsulation material, with preferably each of the two opposite faces of said at least two electrical and/or electronic components facing one of said at least two layers of encapsulation material, said at least one protective element and said at least one deformation absorption element being arranged relatively to at least one of said at least two layers of encapsulation material such that it extends between the assembly formed by said at least one protective element and said at least one deformation absorption element, and said at least one electrical and/or electronic component that they protect.

It should be noted that, before any operation of lamination of the layers, the assembly encapsulating said at least two electrical and/or electronic components preferentially comprises at least two layers of encapsulation material on either side of said at least two electrical and/or electronic components whereas, after lamination, said at least two layers of encapsulation material are mixed and said at least two electrical and/or electronic components are immersed in the encapsulation material of the encapsulating assembly.

“Encapsulated” should be taken to mean that the electrical and/or electronic components are arranged in a volume, for example hermetically sealed, at least in part formed by said at least two layers of encapsulation material.

Furthermore, all the protective elements and all the associated deformation absorption elements may be arranged on a same first layer of encapsulation material of said at least two layers of encapsulation material, the other second layer of encapsulation material of said at least two layers of encapsulation material being notably covered with a base layer, notably of polymeric type.

The assembly of protective elements may thus define the front face of the device, and the base layer may define the rear face of the device.

The device may moreover comprise a plurality of protective elements and at least one part of the protective elements of the electrical and/or electronic device, notably the totality, may form a substantially regular arrangement of polygonal, notably rectangular or square, shapes.

In particular, at least some of the protective elements may be arranged in the form of a checkerboard, comprising a regular distribution of adjacent squares, or put another way even, be arranged in the form of a bar of chocolate. The arrangement of at least some of the protective elements may thus have a paving aspect. Such an aspect may for example make it possible to meet aesthetic expectations.

The protective element(s) may also comprise at least one openwork channel enabling the passage of said at least one electrical contact element.

Thanks to the presence of such an openwork channel in a protective element, the electrical contact element may be protected by the protective element. In particular, it may avoid undergoing mechanical pressure which would risk damaging it.

The protective element(s) may be made of a material having a hardness greater than 60 on the Rockwell M scale, according to the “Standard Test Method for Rockwell Hardness of Plastics and Electrical Insulating Materials” ASTM D785.

The protective element(s) may be made of a material selected from: polymethyl methacrylate (PMMA), polycarbonate or glass, inter alia.

The deformation absorption element(s) may comprise a deformable material or a compressible material such as a highly pressurised gas.

The highly pressurised gas may for example be a gas with a pressure comprised between 5 and 15 bars.

In a variant, the deformation absorption element(s) may comprise transparent polystyrene.

The device may preferentially be a photovoltaic module. Said at least two electrical and/or electronic components may be photovoltaic cells, and notably crystalline photovoltaic cells, or even photovoltaic cells based on amorphous silicon or with thin films such as cells based on CIGS or CdTe, and said at least one electrical contact element may comprise at least one strip of electrically conducting material arranged against the photovoltaic cells and electrically connecting the photovoltaic cells together. The electrical contact element(s) may for example be constituted of a copper strip.

The device according to the invention may furthermore comprise a plurality of protective elements, and may be more rigid at the level of the protective elements than at the level of the connection parts between the protective elements, the suppleness of these connection parts defining the flexibility of the electrical and/or electronic device.

Moreover, the device according to the invention may comprise a plurality of protective elements, and the distance between two successive protective elements may be greater than or equal to 10 mm.

Furthermore, the protective element(s) may for example have a width and/or a length greater than or equal to 100 mm. In particular, the protective element(s) may be substantially in the form of a square of sides greater than or equal to 100 mm.

In an embodiment of the invention, said at least one protective element may be at least partially sunk into at least one of said at least two layers of encapsulation material of the electrical and/or electronic device, notably made of ethylene vinyl acetate (EVA) resin.

In another embodiment of the invention, the device according to the invention may comprise a plurality of protective elements, and the protective elements may be formed by the association of at least two layers of protective material, partially assembled together, notably by heat welding, the superimposed and non-assembled areas of said at least two layers of protective material comprising a gas, notably highly pressurised, to form the corresponding deformation absorption elements.

Furthermore, the electrical contact element(s) may be at least partially flexible, notably in their part situated between said at least two electrical and/or electronic components.

Furthermore, the electrical and/or electronic components may be electronic image sensors and/or electronic display elements.

Furthermore, the invention also relates, according to another of its aspects, to a method for producing an electrical and/or electronic device, notably such as that defined previously, comprising at least the steps of:
a) producing at least two electrical and/or electronic components each comprising two opposite faces,
b) producing at least one electrical contact element arranged against at least one of the two opposite faces of each of said at least two electrical and/or electronic components,
c) producing at least one protective element mechanically protecting each of said at least two electrical and/or electronic components, said at least one protective element being superimposed on said at least one electrical and/or electronic component that it protects such that at least one of the two opposite faces of said at least one electrical and/or electronic component is arranged facing said at least one protective element,
d) producing at least one deformation absorption element, arranged in at least one space formed between said at least one protective element and said at least one electrical and/or electronic component that it protects.
In an embodiment of the method according to the invention, the method may comprise at least the following successive steps:
a) assembling a plurality of electrical and/or electronic components together through the intermediary of a plurality of electrical contact elements, notably by welding,
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer,
c) assembly, notably by bonding, of a plurality of protective elements on the other of the two layers of encapsulation material.
In another embodiment of the method according to the invention, the method may comprise at least the following successive steps:

a) assembling a plurality of electrical and/or electronic components together through the intermediary of a plurality of electrical contact elements, notably by welding,
b) positioning at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, positioning on one of the two layers of encapsulation material at least one base layer, and positioning a plurality of protective elements on the other of the two layers of encapsulation material,
c) laminating the assembly thus formed during the preceding steps such that the plurality of protective elements sink at least partially into said other of the two layers of encapsulation material leading to its fixation to said other of the two layers of encapsulation material.
In yet another embodiment of the method according to the invention, the method may comprise at least the following successive steps:
a) assembling a plurality of electrical and/or electronic components together through the intermediary of a plurality of electrical contact elements, notably by welding,
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer,
c) overmoulding on the other of the two layers of encapsulation material of a print made of a compressible material, notably transparent polystyrene, to form a plurality of deformation absorption elements,
d) overmoulding on the plurality of deformation absorption elements thereby formed of a plurality of protective elements.
In yet another embodiment of the method according to the invention, the method may comprise at least the following successive steps:
a) assembling a plurality of electrical and/or electronic components together through the intermediary of a plurality of electrical contact elements, notably by welding,
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer,
c) partial assembly, notably by heat welding, of at least two layers of protective material to form assembled areas, notably heat welded, and non-assembled areas between said at least two layers of protective material,
d) lamination on the other of the two layers of encapsulation material of the assembly formed during step b), of said at least two layers of protective material partially assembled together, obtained during step c),
e) injection of a gas, notably a highly pressurised gas, into the non-assembled areas of said at least two layers of protective material obtained during step c), to form a plurality of deformation absorption elements of a plurality of protective elements.
Moreover, in another embodiment of the method according to the invention, the method may comprise at least the following successive steps:
a) assembling a plurality of electrical and/or electronic components together through the intermediary of a plurality of electrical contact elements, notably by welding,
b) assembling on either side of the electrical and/or electronic components first protective elements and second protective elements such that the first protective elements, the electrical and/or electronic components and the second protective elements are superimposed together, the first protective elements being assembled to the second protective elements, notably by bonding.

The method according to the invention may comprise any of the aforementioned characteristics, taken in isolation or according to any technically possible combinations thereof with other characteristics.

### BRIEF DESCRIPTION OF THE DRAWINGS

The invention will be better understood on reading the detailed description that follows of exemplary embodiments thereof and by examining the schematic and partial figures of the appended drawing, in which:

FIG. 1 represents, in perspective, a first example of embodiment of an electrical and/or electronic device in compliance with the invention,

FIG. 2 represents a detail of embodiment of the electrical and/or electronic device of FIG. 1,

FIGS. 3A and 3B illustrate, in section, two steps of a first variant of the method for producing an electrical and/or electronic device in compliance with the invention,

FIGS. 4A and 4B illustrate, in section, two steps of a second variant of the method for producing an electrical and/or electronic device in compliance with the invention,

FIGS. 5A and 5B illustrate, in section, two steps of a third variant of the method for producing an electrical and/or electronic device in compliance with the invention,

FIGS. 6A, 6B and 6C illustrate, respectively in section view, in top view and in section view, three steps of a fourth variant of the method for producing an electrical and/or electronic device in compliance with the invention,

FIG. 7A represents, in perspective, another example of producing an electrical and/or electronic device in compliance with the invention,

FIG. 7B is an in section view of the electrical and/or electronic device of FIG. 7A, and

FIG. 8 illustrates, in section, a variant of producing an electrical contact element of an electrical and/or electronic device in compliance with the invention.

In all of these figures, identical references may designate identical or analogous elements.

In addition, the different parts represented in the figures are not necessarily according to a uniform scale, in order to make the figures more legible.

### DETAILED DESCRIPTION OF PARTICULAR EMBODIMENTS

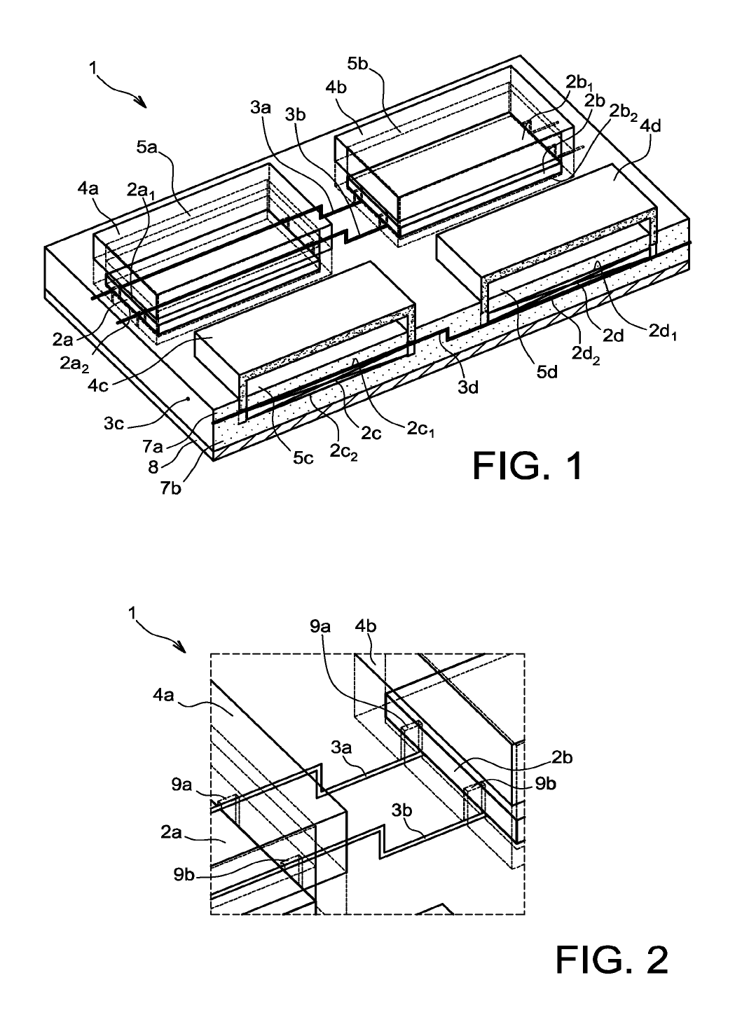

In all the examples described hereafter with reference to FIGS. 1 to 8, it is considered that the electrical and/or electronic devices 1 according to the invention correspond to photovoltaic modules 1, comprising at least four electrical and/or electronic components in the form of photovoltaic cells 2a, 2b, 2c and 2d, notably crystalline photovoltaic cells. Obviously, this choice is in no way limiting.

Reference will firstly be made to FIG. 1 which represents, in perspective, a first example of embodiment of a photovoltaic module 1 in compliance with the invention.

The photovoltaic module 1 comprises four photovoltaic cells 2a, 2b, 2c and 2d, electrically connected together by electrical contact elements 3a, 3b, 3c and 3d, for example in the form of copper strips. In particular, two electrical contact elements 3a and 3b connect the photovoltaic cells 2a and 2b together, and two other electrical contact elements 3c and 3d connect the photovoltaic cells 2c and 2d electrically together.

In addition, the four photovoltaic cells 2a, 2b, 2c and 2d comprise respectively opposite faces 2a₁ and 2a₂, 2b₁ and 2b₂, 2c₁ and 2c₂, and 2d₁ and 2d₂.

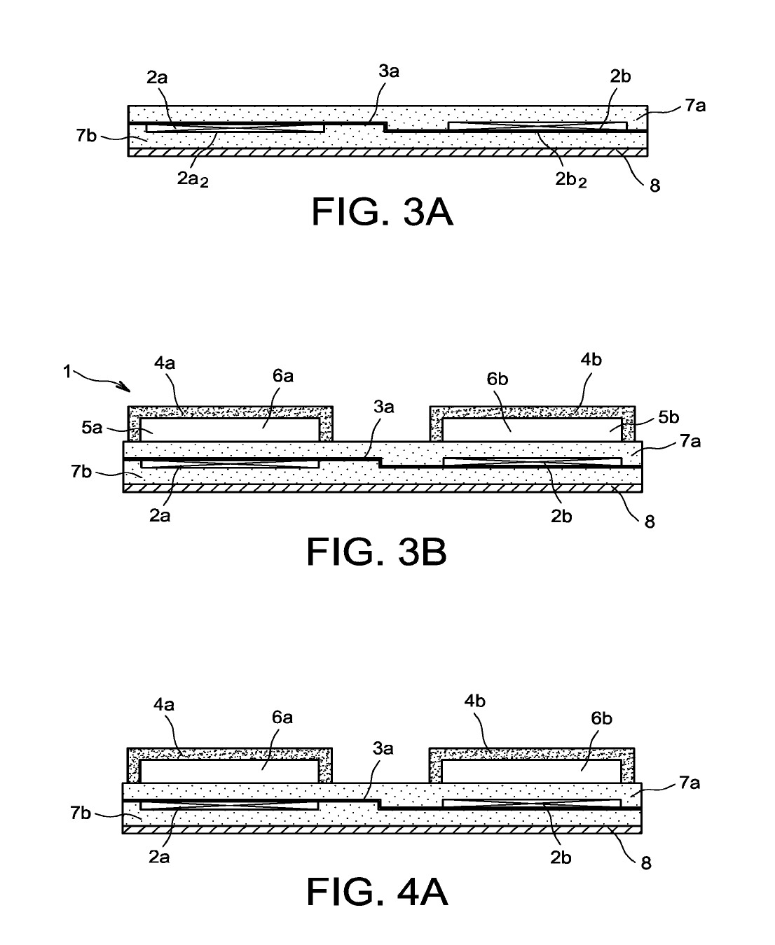

Each of the electrical contact elements 3a, 3b, 3c and 3d may be arranged against one of the two opposite faces of each of the photovoltaic cells 2a, 2b, 2c and 2d, and notably in an alternating manner. Thus, as an example, as may easily be seen in FIG. 3A, the electrical contact element 3a may for example be arranged against the front face 2a₁ of the photovoltaic cell 2a and against the rear face 2b₂ of the photovoltaic cell 2b.

Furthermore, in accordance with the invention, each of the photovoltaic cells 2a, 2b, 2c and 2d is mechanically protected by a protective element 4a, 4b, 4c and 4d.

In particular, in the example of FIG. 1, the four photovoltaic cells 2a, 2b, 2c and 2d are respectively mechanically protected by the four protective elements 4a, 4b, 4c and 4d.

Each of the four protective elements 4a, 4b, 4c and 4d may more particularly be likened to a protective shell or cup.

In the example of FIG. 1, each photovoltaic cell 2a, 2b, 2c and 2d is covered with a single protective shell 4a, 4b, 4c and 4d that is specific thereto. In a variant, although not represented, it could be possible to have a protective element common to at least two photovoltaic cells, that is to say covering at least two photovoltaic cells to protect them mechanically.

The covering of one or more photovoltaic cells by a protective element may in particular depend on the degree of flexibility desired for the photovoltaic module.

Advantageously, the protective shells 4a, 4b, 4c and 4d may be identical, notably in terms of dimensions.

Moreover, in accordance with the invention, the photovoltaic module 1 comprises four deformation absorption elements 5a, 5b, 5c and 5d which are arranged respectively in four spaces 6a, 6b, 6c and 6d formed between the protective shells 4a, 4b, 4c and 4d and the photovoltaic cells 2a, 2b, 2c and 2d.

More particularly, as becomes clearer from the section views of FIGS. 3A to 5B, the spaces 6a, 6b, 6c and 6d comprising the deformation absorption elements 5a, 5b, 5c and 5d are situated respectively between the protective shells 4a, 4b, 4c and 4d and the photovoltaic cells 2a, 2b, 2c and 2d.

Advantageously, the presence of the deformation absorption elements 5a, 5b, 5c and 5d may make it possible to avoid any contact between the photovoltaic cells 2a, 2b, 2c and 2d, and the front face of the photovoltaic module 1, in the present case formed by the four protective shells 4a, 4b, 4c and 4d.

In this way, the association of the protective shells 4a, 4b, 4c and 4d and the absorption elements 5a, 5b, 5c and 5d makes it possible to impart mechanical strength to the photovoltaic module 1, in order to limit, or better to avoid, any risk of damaging the photovoltaic cells 2a, 2b, 2c and 2d, and notably in order to avoid any risk of fissuring. In other words, the photovoltaic cells 2a, 2b, 2c and 2d may be covered by a rigid envelope formed by the protective shells 4a, 4b, 4c and 4d which makes it possible to protect against any mechanical contact with the exterior environment.

It is thus possible to protect the photovoltaic cells 2a, 2b, 2c and 2d while also preserving a maximum of flexibility in the photovoltaic module 1, thanks to the use of a protective shell specific to each photovoltaic cell and to the formation of supple parts of the photovoltaic module 1 between the protective shells 4a, 4b, 4c and 4d.

Throughout the description, and in particular for the protective shells 4a, 4b, 4c and 4d described here, each protective shell may for example be in the form of a main panel with a plurality of peripheral ribs, substantially perpendicular to the main panel, so as to define a reversed U-shaped section. In particular, each protective shell may be geometrically composed of a main panel, substantially planar, horizontal and of rectangular, square or circular shape, and parts forming ribs, substantially vertical and of rectangular, square or circular shape, extending from each side of the main panel. In the case where the main panel is of circular shape, there may exist a single part forming a substantially vertical rib extending from the periphery of the main panel. The parts forming the ribs may optionally be open-worked in order not to bear at the level of the electrical elements. Each protective shell may be produced by assembly of different parts, namely the main panel and the part(s) forming the ribs, in a single piece, for example moulded or thermoformed, inter alia.

The flexibility of the photovoltaic module 1 may enable it to take different shapes to adapt to different types of surfaces on which the photovoltaic module 1 has been arranged, for example surfaces that are stepped, undulating or even of imperfect flatness.

The thickness of the protective shells 4a, 4b, 4c and 4d may be variable, and notably more reduced when it is wished to confer more flexibility to the photovoltaic module 1 according to the invention. In any event, the thickness of the protective shells 4a, 4b, 4c and 4d may depend on the mechanical stresses applied to the photovoltaic module 1.

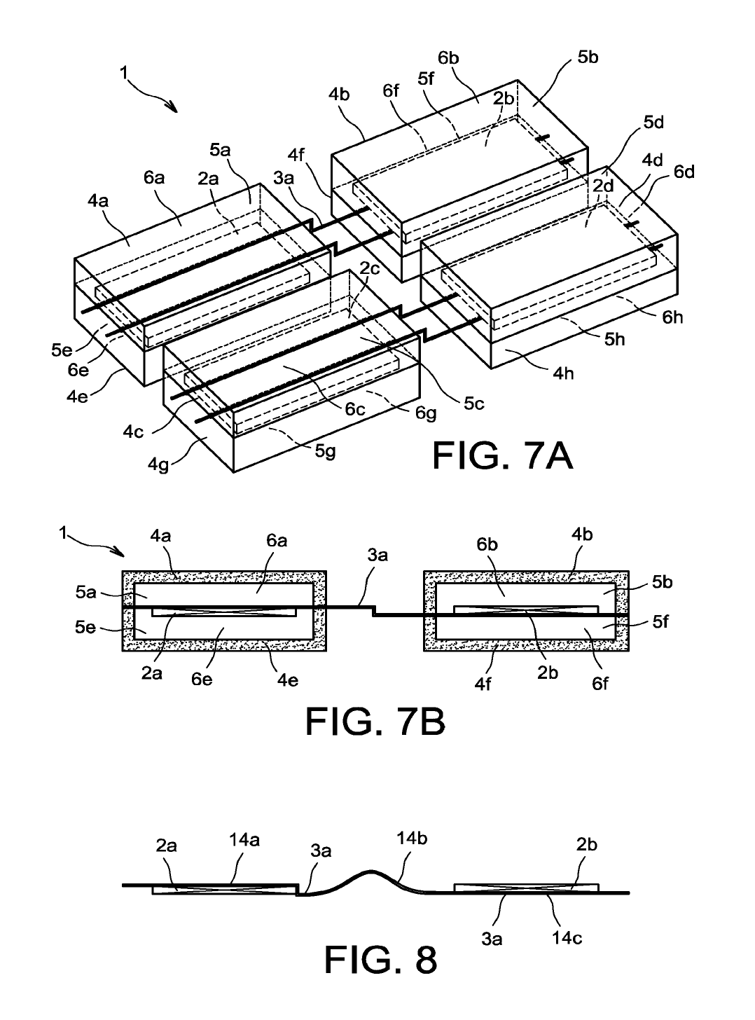

Furthermore, in the example of FIG. 1 but also in the examples of embodiment of FIGS. 3A to 6C, unlike the exemplary embodiment of FIGS. 7A and 7B, the photovoltaic module 1 further comprises two layers of encapsulation material 7a and 7b, between which the four photovoltaic cells 2a, 2b, 2c and 2d are encapsulated, the protective shells 4a, 4b, 4c and 4d and the deformation absorption elements 5a, 5b, 5c and 5d being arranged relatively to one 7a of the two layers of encapsulation material 7a and 7b such that it extends between the assembly formed by the protective shells 4a, 4b, 4c and 4d and the deformation absorption elements 5a, 5b, 5c and 5d, and the photovoltaic cells 2a, 2b, 2c and 2d that they protect.

The other 7b of the two layers of encapsulation material 7a and 7b is furthermore covered with a base layer 8, notably of the polymeric type, which defines the rear face of the photovoltaic module 1, whereas the protective shells 4a, 4b, 4c and 4d, preferentially transparent, define the front face of the photovoltaic module 1.

It should be noted that, advantageously, the four protective shells 4a, 4b, 4c and 4d form between them a regular pattern, notably in the form of a bar of chocolate.

This regular shape in the arrangement of the protective shells 4a, 4b, 4c and 4d may make it possible to improve the modularity and the flexibility of the photovoltaic module 1, and also makes it possible to respond to aesthetic expectations.

Thanks to the presence of the protective shells 4a, 4b, 4c and 4d associated with the use of deformation absorption elements 5a, 5b, 5c and 5d, it is thus possible to avoid loading the photovoltaic cells 2a, 2b, 2c and 2d by external mechanical stresses. The invention thus makes it possible to impart the necessary robustness to the photovoltaic module 1 to protect the photovoltaic cells 2a, 2b, 2c and 2d.

It should moreover be noted that each of the protective shells 4a, 4b, 4c and 4d may be made of a flexible material, such that the photovoltaic module may, if need be, be folded or rolled as a function of the needs of the targeted applications.

Each of the protective shells 4a, 4b, 4c and 4d may for example be made from a material selected from: polymethyl methacrylate (PMMA), polycarbonate or glass.

Moreover, each of the deformation absorption elements 5a, 5b, 5c and 5d advantageously comprises a deformable material. In particular, in the example of FIG. 1 and FIGS. 3B, 4A-4B, 6C and 7B, the deformation absorption elements comprise a highly pressurised gas, notably with a pressure comprised between 5 and 15 bars.

In a variant, the deformation absorption elements may be selected from other types of materials, and notably comprise transparent polystyrene, as will be described with reference to FIGS. 5A and 5B hereafter.

A detail of embodiment of the photovoltaic module 1 of FIG. 1, and in particular the area situated between the two photovoltaic cells 2a and 2b, is furthermore represented in FIG. 2.

As may be seen in this FIG. 2, each of the protective shells 4a, 4b, 4c and 4d may comprise at least one openwork channel 9a or 9b to enable the passage of an electrical contact element 3a, 3b, 3c or 3d.

More specifically, in FIG. 2, the protective shell 4a comprises an openwork channel 9a to enable the passage of the electrical contact element 3a and an openwork channel 9b to enable the passage of the electrical contact element 3b. Similarly, the protective shell 4b comprises an openwork channel 9a to enable the passage of the electrical contact element 3a and an openwork channel 9b to enable the passage of the electrical contact element 3b.

In this manner, thanks to the presence of openwork channels 9a and 9b formed in the protective shells 4a and 4b, it may be possible to protect the electrical contact elements 3a and 3b from any mechanical pressure that could be exerted on the protective shells 4a and 4b.

Four variants of the method for producing a photovoltaic module 1 in compliance with the invention will now be described hereafter, with reference to FIGS. 3A to 6C.

In each of these variants, the method comprises at least the steps consisting in:
a) producing four photovoltaic cells 2a, 2b, 2c and 2d each comprising two opposite faces 2a₁ and 2a₂, 2b₁ and 2b₂, 2c₁ and 2c₂, and 2d₁ and 2d₂,
b) producing four electrical contact elements 3a, 3b, 3c and 3d to connect the four photovoltaic cells 2a, 2b, 2c and 2d electrically together,
c) producing four protective elements or shells 4a, 4b, 4c and 4d to protect mechanically each of the four photovoltaic cells 2a, 2b, 2c and 2d,
d) producing four deformation absorption elements 5a, 5b, 5c and 5d which are arranged respectively in four spaces 6a, 6b, 6c and 6d formed between the four protective shells 4a, 4b, 4c and 4d and the four photovoltaic cells 2a, 2b, 2c and 2d.

FIGS. 3A and 3B firstly illustrate, in section, two steps of a method for producing a photovoltaic module 1 in compliance with the invention, by lamination then bonding.

Thus, photovoltaic cells 2a, 2b, 2c and 2d having for example the shape of a square of side equal to 100 mm are firstly produced, these photovoltaic cells 2a, 2b, 2c and 2d being for example mini-cells cut from cells of larger dimensions, and for example cells having a square shape with sides equal to 156 mm.

These four photovoltaic cells 2a, 2b, 2c and 2d are then assembled together by welding, in accordance with the method of assembly according to the prior art, through the intermediary of electrical contact elements 3a, 3b, 3c and 3d, for example in the form of tinned copper strips.

Then, as is illustrated in FIG. 3A, once the photovoltaic cells 2a, 2b, 2c and 2d are electrically connected together, they are laminated on either side with layers of encapsulation material 7a and 7b, and a base layer 8 constituting the rear face of the photovoltaic module 1.

The layers of encapsulation materials 7a and 7b may for example be constituted of the resin EVA. Nevertheless, in a variant, the use of the resin EVA could be replaced by other types of transparent resins, and for example selected from the family of polyurethanes, polyolefins, for example modified polyolefin or ionomer, or instead polyvinyl butylene. As an example, it is possible for example to use commercially available products such as Apolhya® of the Arkema company, CVF® of the DNP Solar Company or Jurasol DG3® of the Juraplast Company.

The base layer 8 is for example constituted of a multilayer polymer, for example based on polyvinyl fluoride (PVF) or polyethylene terephthalate (PET). As an example, Tedlar® of the Dupont Company may be cited.

The nature of the base layer 8, as well as its thickness, may vary as a function of the desired type of protection vis-à-vis the rear face of the photovoltaic module 1, and also as a function of the flexibility expected for the photovoltaic module 1.

In a variant, the base layer 8 may also comprise a metal layer for example made of steel, optionally protected by an additional covering, notably an insulating covering, for example of the polyurethane type, for example of the Pu Damival® type of the Vonrol Company.

Furthermore, the protective shells 4a, 4b, 4c and 4d are made of PMMA, in particular made of the so-called “impact PMMA” material sold by the Arkema Company under the reference Altugas® ShieldUp. In a variant, the protective shells 4a, 4b, 4c and 4d may also be made of polycarbonate, such as for example from Macrolon® of the Bayer Company, or even more preferentially for impact resistance, from Lexan® sold by the Sabic Company.

Then, as illustrated in FIG. 3B, the protective shells 4a, 4b, 4c and 4d are bonded onto the layer of encapsulation material 7a, for example by means of an acrylic adhesive. The protective shells 4a, 4b, 4c and 4d are for example spaced apart by at least 10 mm.

Furthermore, before assembly of the protective shells 4a, 4b, 4c and 4d on the layer of encapsulation material 7a, a highly pressurised gas is introduced between each protective shell 4a, 4b, 4c and 4d and the layer of encapsulation material 7a to form each of the four deformation absorption elements 5a, 5b, 5c and 5d. The use of a highly pressurised gas may also make it possible to reduce the thickness of the protective shells 4a, 4b, 4c and 4d. In a variant, although this is less satisfactory, each deformation absorption element 5a, 5b, 5c and 5d could be formed by the surrounding air.

Advantageously, the four deformation absorption elements 5a, 5b, 5c and 5d make it possible to compensate for potential deformations linked to mechanical pressure on the protective shells 4a, 4b, 4c and 4d, and above all to prevent contact between the protective shells 4a, 4b, 4c and 4d and the photovoltaic cells 2a, 2b, 2c and 2d.

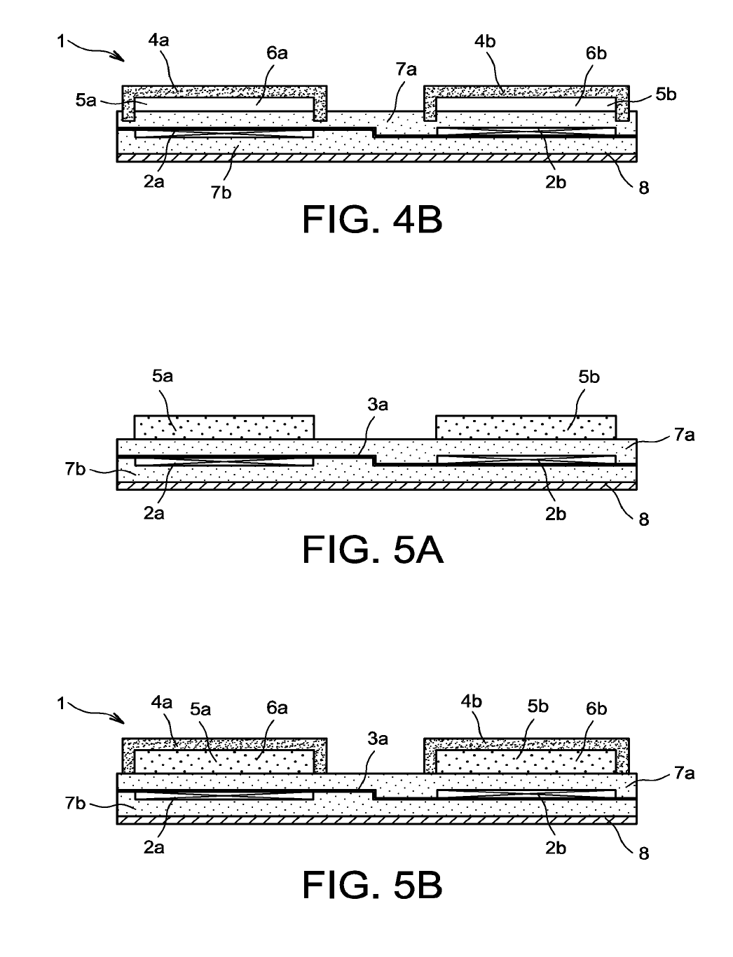

In FIGS. 4A and 4B are also illustrated, in section, the steps of another variant of method for producing a photovoltaic module 1 in compliance with the invention.

In this variant, the photovoltaic module 1 is produced by a complete lamination of its constituent layers.

In particular, as illustrated in FIG. 4A, the layers of encapsulation material 7a and 7b may be positioned on either side of the photovoltaic cells 2a, 2b, 2c and 2d. In addition, the base layer 8 may also be positioned in contact with the layer of encapsulation material 7b. The protective shells 4a, 4b, 4c and 4d are also positioned in contact with the layer of encapsulation material 7a. This positioning of the layers relatively to each other is carried out before lamination.

Then, as illustrated in FIG. 4B, a phase of lamination of the layers is engaged, during which the resin of the layer of encapsulation material 7a is going to melt such that each of the protective shells 4a, 4b, 4c and 4d is going to sink in and be fixed in this layer of encapsulation material 7a.

Furthermore, as described previously, it may be provided to inject a highly pressurised gas to form the deformation absorption elements 5a, 5b, 5c and 5d. FIGS. 5A and 5B illustrate, in section, another alternative embodiment of the method according to the invention. In this variant, overmoulding is used.

In particular, as illustrated in FIG. 5A, after lamination of the layers of encapsulation material 7a and 7b on either side of the photovoltaic cells 2a, 2b, 2c and 2d and lamination of a base layer 8, above the photovoltaic cells 2a, 2b, 2c and 2d, on the layer of encapsulation material 7a, is overmoulded a print (or guide) made of a very compressible material, such as for example transparent expanded polystyrene, to form the deformation absorption elements 5a, 5b, 5c and 5d. Then, as illustrated in FIG. 5B, secondly, on the deformation absorption elements 5a, 5b, 5c and 5d is overmoulded the robust material constituting the protective shells 4a, 4b, 4c and 4s, for example made of PMMA.

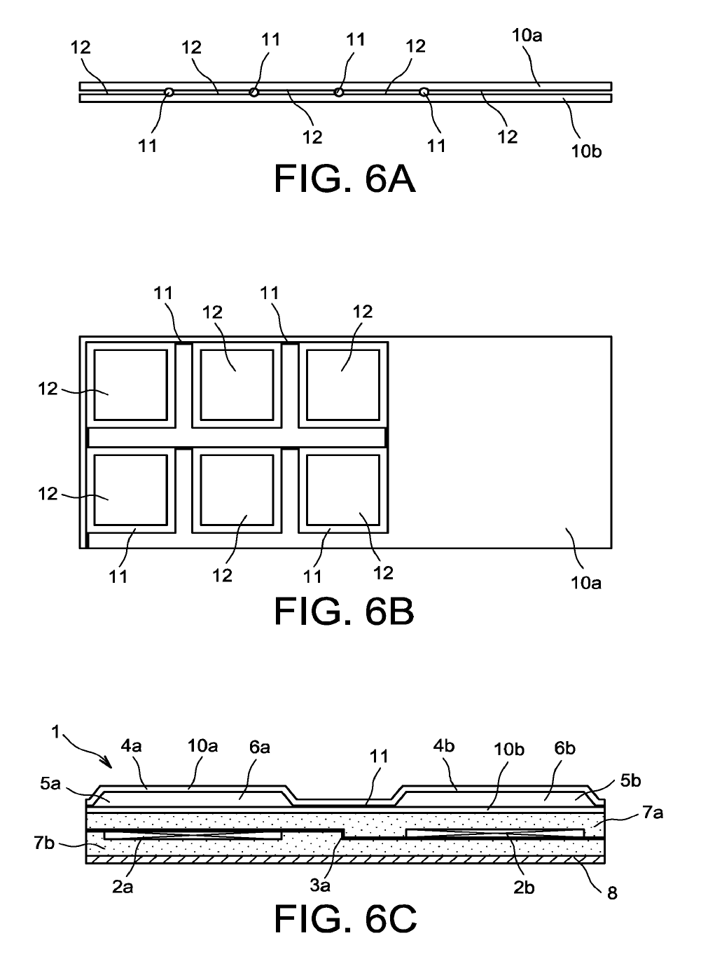

Another example of carrying out a method in compliance with the invention is furthermore illustrated in FIGS. 6A to 6C. In this variant, a blowing method is used to form the protective shells 4a, 4b, 4c and 4d and the deformation absorption elements 5a, 5b, 5c and 5d.

Thus, as illustrated in FIG. 6A, in section, the first step consists in heat welding together two layers of protective material 10a and 1013, for example formed by films made of PMMA, in order to form squares (visible in FIG. 6B).

In particular, the two layers of protective material 10a and 10b are partially heat welded together so as to form areas assembled by heat welding 11 and areas 12 superimposed but not assembled together.

Thus, as illustrated in front view in FIG. 6B, a set of non-assembled areas 12 in the form of squares are obtained, on which is provided furthermore an opening to give the possibility of injection of a gas, for example air or nitrogen, during the third step described with reference to FIG. 6C.

During this third step, illustrated in FIG. 6C in section, the two layers of protective material 10a and 10b, such as obtained during the step illustrated with reference to FIG. 6B, are laminated on an assembly of the photovoltaic module 1 such as obtained for example with reference to FIG. 3A.

Then, into the photovoltaic module 1, at the level of the opening 13 as represented in FIG. 6B, is injected a highly pressurised gas, for example at a pressure comprised between 5 and 15 bars, so that it penetrates inside the non-assembled areas 12 to form the deformation absorption elements 5a and 5b, as well as the protective shells 4a and 4b.

Another example of producing a photovoltaic module 1 in compliance with the invention is moreover illustrated in perspective in FIG. 7A and in section in FIG. 7B.

In this example, the photovoltaic module 1 is without a base layer 8 and layers of encapsulation material 7a and 7b as described previously.

In reality, each of the four photovoltaic cells 2a, 2b, 2c and 2d is covered on either side by a first protective element 4a, 4b, 4c and 4d and a second protective element 4e, 4f, 4g and 4h. In particular, as represented in FIG. 7B, the first protective elements 4a, 4b, 4c and 4d are superimposed on the second protective elements 4e, 4f, 4g and 4h, such that each of the photovoltaic cells 2a, 2b, 2c and 2d is enveloped by these first and second protective elements.

In this way, the photovoltaic cells 2a, 2b, 2c and 2d no longer rest on a supple substrate such as formed by encapsulation by use of layers of encapsulation material 7a and 7b, as described previously. On the contrary, they are sandwiched between two protective shells.

This embodiment may enable a simplified assembly of the photovoltaic cells together. In particular, it may no longer be necessary to encapsulate the photovoltaic cells together.

Similarly, it may no longer be necessary to assemble, notably by welding, the electrical contact elements over the whole width of the photovoltaic cells. Indeed, a welding is normally carried out over the whole width of the photovoltaic cells for the assembly of the electrical contact elements in order to avoid being hindered by the resin constituting the layers of encapsulation material 7a and 7b. Nevertheless, without use of such layers of encapsulation material 7a and 7b, a partial welding may be sufficient.

Advantageously, this embodiment of FIGS. 7a and 7b may make it possible to protect the photovoltaic cells 2a, 2b, 2c and 2d from exterior stresses at the level of each of their opposite faces. This embodiment may make it possible to obtain a bifacial configuration of the photovoltaic module 1.

Furthermore, FIG. 8 illustrates, in section and in a simplified manner, the possibility of having an electrical contact element 3a which is at least partially flexible, and notably in the part thereof situated between two photovoltaic cells 2a and 2b.

More specifically, in certain configurations of use of the photovoltaic module 1, the electrical contact elements may be mechanically loaded and may consequently weaken the photovoltaic cells. In this case, it may be necessary to provide sufficiently supple electrical contact elements.

To do so, a first possibility may consist in playing on the ratio between the thickness and the width of each electrical contact element.

A second possibility may consist in replacing the usual copper strip forming the electrical contact element by a desoldering braid, as taught for example by the international patent application WO 2012/028537 A1.

Finally, a third possibility, illustrated with reference to FIG. 8, may consist in using at least one flexible portion 14b in the area of the electrical contact element 3A situated between the photovoltaic cells 2a and 2b.

Thus, the electrical contact element 3a may for example comprise two rigid portions 14a and 14c respectively assembled to the two photovoltaic cells 2a and 2b, for example by welding or bonding, and comprise a central flexible portion 14b making the link between the two rigid portions 14a and 14c.

Obviously, the invention is not limited to the examples of embodiment that have been described. Various modifications may be made thereto by those skilled in the art.

The expression “comprising a” should be understood as being synonymous with “comprising at least one”, unless specified otherwise.

1-20. (canceled)

21: An electrical and/or electronic device comprising:
at least two electrical and/or electronic components, each of the at least two electrical and/or electronic components comprising two opposite faces;
at least one electrical contact element arranged against at least one of the two opposite faces of each of the at least two electrical and/or electronic components;
wherein each electrical and/or electronic component is mechanically protected by two protective elements which are specific thereto, being taken between the two protective elements, a first protective element being arranged in superposition with respect to the electrical and/or electronic component that it protects, facing one of its two opposite faces, and a second protective element being arranged in superposition with respect to the electrical and/or electronic component that it protects, facing the other of its two opposite faces; and
wherein least one deformation absorption element is arranged in at least one space formed between at least one protective element and the electrical and/or electronic component that it protects.

22: A device according to claim 21, wherein the first protective element and the second protective element are assembled together.

23: A device according to claim 21, wherein the first protective element and the second protective element form respectively, at least in part, front and rear faces of the electrical and/or electronic device, between which are only arranged the electrical and/or electronic component, that the first and second protective elements protect, the at least one electrical contact element that is associated with it and at least one first deformation absorption element and a second absorption element arranged on either side of the electrical and/or electronic component.

24: A device according to claim 21, comprising a plurality of protective elements, and wherein at least one part of the protective elements of the electrical and/or electronic device forms a substantially regular arrangement of polygonal.

25: A device according to claim 21, wherein the at least one protective element comprises at least one openwork channel enabling passage of the at least one electrical contact element.

26: A device according to claim 21, wherein the at least one protective element is made of a material having a hardness greater than 60 on the Rockwell M scale, according to the Standard Test Method for Rockwell Hardness of Plastics and Electrical Insulating Materials ASTM D785.

27: A device according to claim 21, wherein the at least one protective element is made from a material selected from: polymethyl methacrylate (PMMA), polycarbonate, or glass.

28: A device according to claim 21, wherein the at least one deformation absorption elements comprises a deformable material.

29: A device according to claim 28, wherein the at least one deformation absorption element comprises a compressible material.

30: A device according to claim 28, wherein the at least one deformation absorption element comprises transparent polystyrene.

31: A device according to claim 21, which is a photovoltaic module, the at least two electrical and/or electronic components being photovoltaic cells, and the at least one electrical contact element comprising at least one strip of electrically conducting material arranged against the photovoltaic cells and electrically connecting the photovoltaic cells together.

32: A device according to claim 21, comprising a plurality of protective elements, and being more rigid at a level of the protective elements than at a level of the connection parts between the protective elements, suppleness of the connection parts defining flexibility of the electrical and/or electronic device.

33: A device according to claim 31, comprising a plurality of protective elements, and wherein the protective elements are formed by association of at least two layers of protective material, partially assembled together, superimposed and non-assembled areas of the at least two layers of protective material comprising a gas to form corresponding deformation absorption elements.

34: A device according to claim 21, wherein the at least one electrical contact element is at least partially flexible, in a part thereof situated between the at least two electrical and/or electronic components.

35: A method for producing an electrical and/or electronic device, comprising:
a) producing at least two electrical and/or electronic components each comprising two opposite faces;
b) producing at least one electrical contact element arranged against at least one of the two opposite faces of each of the at least two electrical and/or electronic components;
c) producing at least one protective element mechanically protecting each of the at least two electrical and/or electronic components, each electrical and/or electronic component being mechanically protected by two protective elements which are specific thereto, being taken between the two protective elements, a first protective element being arranged in superposition with respect to the electrical and/or electronic component that it protects, facing one of its two opposite faces, and a second protective element being arranged in superposition with respect to the electrical and/or electronic component that it protects, facing the other of its two opposite faces;
d) producing at least one deformation absorption element, arranged in at least one space formed between the at least one protective element and the electrical and/or electronic component that it protects.

36: A method according to claim 35, comprising successively:
a) assembling a plurality of electrical and/or electronic components together through intermediary of a plurality of electrical contact elements;
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer;
c) assembly of a plurality of protective elements on the other of the two layers of encapsulation material.

37: A method according to claim 35, comprising successively:
a) assembling a plurality of electrical and/or electronic components together through intermediary of a plurality of electrical contact elements;
b) positioning at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, positioning on one of the two layers of encapsulation material at least one base layer, and positioning a plurality of protective elements on the other of the two layers of encapsulation material;
c) laminating the assembly thereby formed during the preceding steps such that the plurality of protective elements sinks at least partially into the other of the two layers of encapsulation material leading to fixation thereof to the other of the two layers of encapsulation material.

38: A method according to claim 35, comprising successively:
a) assembling a plurality of electrical and/or electronic components together through intermediary of a plurality of electrical contact elements;
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer;
c) overmolding on the other of the two layers of encapsulation material of an imprint in a compressible material, to form a plurality of deformation absorption elements;
d) overmolding on the plurality of deformation absorption elements thus formed of a plurality of protective elements.

39: A method according to claim 35, comprising successively:
a) assembling a plurality of electrical and/or electronic components together through intermediary of a plurality of electrical contact elements;
b) laminating at least two layers of encapsulation material on either side of the plurality of electrical and/or electronic components to form an assembly encapsulating the electrical and/or electronic components, each of the two opposite faces of the electrical and/or electronic components being arranged facing one of the two layers of encapsulation material, and lamination on one of the two layers of encapsulation material of at least one base layer;
c) partial assembly, of at least two layers of protective material to form assembled areas, and non-assembled areas between the at least two layers of protective material;
d) lamination on the other of the two layers of encapsulation material of the assembly formed during b), of the at least two layers of protective material partially assembled together, obtained during c);
e) injection of a gas into the non-assembled areas of the at least two layers of protective material obtained during c), to form a plurality of deformation absorption elements of a plurality of protective elements.

40: A method according to claim 35, comprising successively:
a) assembling a plurality of electrical and/or electronic components together through intermediary of a plurality of electrical contact elements;
b) assembling on either side of the electrical and/or electronic components first protective elements and second protective elements, such that the first protective elements, the electrical and/or electronic components and the second protective elements are superimposed together, the first protective elements being assembled on the second protective elements.
